(19) United States
(12) Patent Application Publication
(10) Pub. No.: US 2009/0116221 A1
(43) Pub. Date: May 7, 2009

(54) SURFACE LIGHT EMITTER AND DISPLAY DEVICE

(75) Inventors: Akira Sato, Tokyo (JP); Manami Kuiseko, Kyoto (JP)

Correspondence Address: LUCAS & MERCANTI, LLP, 475 PARK AVENUE SOUTH, 15TH FLOOR, NEW YORK, NY, 10016, US

(73) Assignee: KONICA MINOLTA HOLDINGS, INC., Tokyo (JP)

(21) Appl. No.: 12/302,124

(22) PCT Filed: May 21, 2007
(86) PCT No.: PCT/JP2007/060355

§ 371 Date: Nov. 24, 2008

(30) Foreign Application Priority Data
May 31, 2006 (JP) 2006-151381

(51) Int. Cl. G09F 13/08; F21V 33/00

(52) U.S. Cl. 362/97.1; 362/257; 362/311.01

(57) ABSTRACT

In the present invention, provided is a surface light emitter in which an amount of light emitted from the surface light emitter and front luminance are designed to be increased, and generation of moire images is also designed to be inhibited, and also provided is a display device employing the surface light emitter as a backlight. Also disclosed is a surface light emitter possessing at least a light control sheet and a surface light-emitting device, wherein the light control sheet comprises protrusions provided on a surface of the light control sheet, and tip portions of the protrusions are attached to a light emission surface of the surface light-emitting device through an adhesion layer, and wherein the light control sheet has a haze value of at least 85%.

### TECHNICAL FIELD

The present invention relates to a surface light emitter equipped with a surface light-emitting device, and to the surface light emitter designed to increase an amount of light emitted from the surface light emitter and front luminance, and a display device employing the surface light emitter as a backlight.

### BACKGROUND

In recent years, with diversification of information technology apparatuses, there is an increasing demand for small sized surface light-emitting devices with low power consumption, and attention has been focused on electroluminescent devices (hereinafter abbreviated as EL devices) as such the surface light-emitting device.

Such the EL devices are broadly classified into inorganic EL devices and organic EL devices depending on the utilized material.

Further, in the case of inorganic EL devices, generally a high electric field is applied to the light emitting portion, and electrons are accelerated by the high electric field to collide with the luminescent center, thus the luminescent center is excited to produce luminescence. On the other hand, in the case of organic EL devices, electrons and holes are injected respectively from an electron injection electrode and a hole injection electrode into an emission layer, an organic material is in an excited state, and luminescence is caused when this organic material returns from the excited state to the ground state. And organic EL devices have the advantage of being able to be driven at a lower voltage in comparison to the inorganic EL devices.

Further, in the case of organic EL devices, it is possible to obtain light-emitting devices that produce luminescence with appropriate color by selecting appropriate light-emitting materials, it is also possible to obtain white light by suitably combining light-emitting materials, and hence they are also expected to be used as the backlight for display devices such as liquid crystal display elements and so forth.

In cases where the backlight is utilized for a liquid crystal display element, a front luminance of 2000-4000 cd/m² is usually desired, but when light is emitted employing a surface light-emitting device such as the above-described EL device and so forth, the emitted light travels in all directions, and a lot of light is totally reflected on the light emission surface of the surface light-emitting device, and is kept inside the surface light-emitting device, whereby it is difficult to obtain sufficient front luminance. Particularly in the case of organic EL devices, there was a problem such that it was possible to obtain a front luminance of only about 1000-1500 cd/m² in order to obtain sufficient light emission lifetime. Accordingly, a light outputting efficiency of at least 1.4-fold magnification, a front luminance of at least 1.6-fold magnification are desired as a measure, and a front luminance of at least 2-fold magnification is further preferred.

Conventionally, when light is emitted from a surface light-emitting device such as an organic EL device or the like, disclosed have been those to provide a diffusion structure on the light emission surface of the surface light-emitting device to output light kept inside the surface light-emitting device in order to improve its front luminance, (refer to Patent Documents 1, 2, 3 and 4, for example), and to provide a prism or a lenticular sheet on the light emission surface of the surface light-emitting device so as to show up on the surface as convexoconcave (refer to Patent Documents 5, 6, 7 and 8, for example).

However, as described above, when the fine convexoconcave is designed to be provided on the light emission surface of the surface light-emitting device, or when a flat member is designed to be provided on the light emission surface of the surface light-emitting device so as to show up on the surface as the convexoconcave, there has been a problem such that light is dispersed because of the convexoconcave present on the surface, whereby the front luminance can not yet be sufficiently improved.

As another means to improve front luminance of a surface light-emitting device such as an organic EL light-emitting device and so forth, disclosed is a structure in which a prism array sheet having convexoconcave on the surface is provided on the light emission surface so as to have the prism side facing the light emission surface (refer to Patent Documents 9 and 10 for example). In the case of such the structure, prism lines reflected on the back surface of a light-emitting device through an adhesion portion are observed since transparency (property of light transmission with no dispersion) of the adhesion portion of the prism is high. In this case, when prism lines are regularly arranged, a moire image is undesirably generated via observation since the prism lines and a specular image of the prism lines observed via back surface reflection are superposed.

Patent Document 1: Japanese Patent O.P.I. Publication No. 2000-323272

Patent Document 2: Japanese Patent O.P.I. Publication No. 2000-231985

Patent Document 3: Japanese Patent O.P.I. Publication No. 7-162037

Patent Document 4: Japanese Patent O.P.I. Publication No. 11-111464

Patent Document 5: Japanese Patent O.P.I. Publication No. 2005-63926

Patent Document 6: Japanese Patent O.P.I. Publication No. 2003-59641

Patent Document 7: Japanese Patent O.P.I. Publication No. 6-265888

Patent Document 8: Japanese Patent O.P.I. Publication No. 2005-353431

Patent Document 9: Japanese Patent O.P.I. Publication No. 2000-148032

Patent Document 10. Japanese Patent O.P.I. Publication No. 2006-59543

### DISCLOSURE OF THE INVENTION

### Problems to be Solved by the Invention

The present invention was made on the basis of the above-described situation, and in a surface light emitter equipped with a surface light-emitting device and a display device employing the surface light emitter, it is a target to improve an outputting efficiency of light emitted from the surface light emitter.

Accordingly, it is an object of the present invention to provide a surface light emitter and a display device employing the surface light emitter as the backlight, in which a moire image is designed to be controllable by increasing an amount of light emitted from the surface light emitter.

### Means to Solve the Problems

The above-described object of the present invention is accomplished by the following Structures.

Structure 1: A surface light emitter of the present invention comprising a light control sheet and a surface light-emitting device, wherein the light control sheet comprises protrusions provided on a surface of the light control sheet, and tip portions of the protrusions are attached to a light emission surface of the surface light-emitting device through an adhesion layer, and wherein the light control sheet has a haze value of at least 85%.

Structure 2: A surface light emitter of the present invention comprising a diffusion sheet, a light control sheet and a surface light-emitting device, wherein the light control sheet comprises protrusions provided on a surface of the light control sheet; tip portions of the protrusions are attached to a light emission surface of the surface light-emitting device through an adhesion layer; and the diffusion sheet is provided on an opposite side surface of the light control sheet with respect to a surface of the light control sheet brought into contact with the surface light-emitting device, and wherein the light control sheet has a haze value of less than 80%.

Structure 3: A surface light emitter of the present invention comprising a light control sheet and a surface light-emitting device, wherein the light control sheet comprises protrusions provided on a surface of the light control sheet and a diffusion structure provided on another surface of the light control sheet, and tip portions of the protrusions are attached to a light emission surface of the surface light-emitting device through an adhesion layer, and wherein the diffusion structure has a reflectance of less than 35%.

Structure 4: A surface light emitter of the present invention comprising a light control sheet and a surface light-emitting device, wherein the light control sheet comprises protrusions provided on a surface of the light control sheet, and tip portions of the protrusions are attached to a light emission surface of the surface light-emitting device through an adhesion layer, and wherein the adhesion layer has a diffusion structure.

Structure 5: A surface light emitter of the present invention comprising a light control sheet and a surface light-emitting device, wherein the light control sheet comprises protrusions provided on a surface of the light control sheet, and tip portions of the protrusions are attached to a light emission surface of the surface light-emitting device through an adhesion layer, and wherein the surface light-emitting device comprises a surface of a transparent substrate having a diffusion structure as a light emission surface.

Structure 6: The surface light emitter of any one of Structures 1-5 in the present invention, wherein the protrusions are truncated cone-shaped.

Structure 7: A display device comprising the surface light emitter of any one of Structures 1-6 described in the present invention as a backlight.

### EFFECT OF THE INVENTION

In the present invention, provided is a surface light emitter in which an amount of light emitted from the surface light emitter and front luminance are designed to be increased, and generation of moire images is also designed to be inhibited, and also provided is a display device employing the surface light emitter as a backlight.

### BRIEF DESCRIPTION OF THE DRAWINGS

FIG. 1(a) shows an example of an prism array sheet in the present invention, and FIG. 1(b) shows another example of an prism array sheet in the present invention.

FIG. 2 shows an example of an embodiment of a surface light emitter in the present invention.

FIG. 3 is a schematic diagram showing light emission from a surface light emitter in the present invention.

FIG. 4 is a schematic diagram showing a mechanism concerning generation of moire images.

FIG. 5(a) shows an example of a surface light emitter possessing truncated cone-shaped protrusions, and FIG. 5(b) shows another example of a surface light emitter possessing truncated cone-shaped protrusions.

FIG. 6 shows an example of a surface light emitter possessing a diffusion sheet.

FIG. 7 shows an example of a surface light emitter possessing a diffusion structure provided on a surface on the side of an observer.

FIG. 8 shows an example of a surface light emitter possessing an adhesive diffusion layer exhibiting diffuseness.

FIG. 9 shows an example of a surface light emitter employing a diffusion substrate having a diffusion structure as a transparent substrate.

FIG. 10 shows a surface light emitter composed of an organic EL device possessing an organic EL layer and a facing electrode provided on the surface of a transparent substrate.

### EXPLANATION OF NUMERALS

10A and 10E Prism array sheet
11 Transparent substrate
12 Protrusions
13 Space part
14 Light emission surface
20 Surface light-emitting device
21 Transparent substrate
22 Transparent electrode
23 Organic EL device
24 Facing electrode

### DESCRIPTION OF THE PREFERRED EMBODIMENTS

The preferred embodiments of the present invention will be described below, but the present invention is not limited thereto.

As to a surface light emitter of the present invention, a light control sheet possesses protrusions provided on a surface of the light control sheet, and tip portions of the protrusions are attached to a light emission surface of the surface light-emitting device through an adhesion layer to introduce light into a light control sheet, and also in the case of no light control sheet provided, light totally reflected on a light emission surface of the surface light emitter is to be introduced into this light control sheet with no reflection at the portions onto which tip surfaces of protrusions in the light control sheet are attached.

Herein, examples of protrusions include truncated pyramid-shaped protrusions, truncated cone-shaped protrusions and so forth.

What tip portions of the protrusions are attached to a light emission surface of a surface light-emitting device through an adhesion layer means that all the protrusions are not embedded in an adhesion layer, and a part of the protrusions is attached to the light emission surface of the surface light-emitting device through the adhesive, resulting in formation of spacing between the surface light-emitting device and a light control sheet. A large amount of light introduced into the light control sheet is totally reflected at the interface between the space portion and the protrusion contracted toward the light emission surface of the surface light-emitting device, and light totally reflected is introduced into the light emission surface of the light control sheet to produce luminescence.

As the result, in the case of a surface light emitter of Structure 1 in the present invention, an outputting efficiency of light emitted through the above-described light control sheet is improved, and front luminance is largely improved.

In this case, since a specular image of a light control sheet, obtained via reflection on the mirror surface as a back surface of a surface light emitter after transmitting protrusions of the light control sheet, is observed, a moire image in protrusions of the light control sheet arrayed regularly is produced, but it becomes difficult to observe the moire image when the light control sheet has a haze value of at least 85%.

A light control sheet was attached onto a transparent glass substrate in the same structure as that in use to measure a haze value of the light control sheet which is the value measured employing a haze meter (for example, HazeMeter NDH2000, manufactured by NIPPON DENSHOKU Industries Co., Ltd.).

Further, in the case of a surface light emitter of Structure 1, when protrusions provided on a surface of the above-described light control sheet are formed in the form of a truncated cone contracted toward the above-described tip surfaces, an outputting efficiency of light emitted through this light control sheet is improved, and front luminance is further improved.

In the case of a surface light emitter of Structure 2 in the present invention, similarly to the surface light emitter of Structure 1, a large amount of light introduced into a light control sheet after passing through tip surfaces of protrusions of an attached light control sheet is totally reflected at the interface between the space portion and the protrusion, and light totally reflected is introduced into a light emission surface of the light control sheet to produce luminescence. As the result, a light outputting efficiency is improved, and front luminance is largely improved. In this case, since a specular image of a light control sheet, obtained via reflection on the mirror surface as a back surface of a surface light emitter after transmitting protrusions of the light control sheet, is observed, moire images are to be generated, but no moire fringe is visualized when a diffusion sheet is provided on the light control sheet.

A situation where no moire fringe can be visualized with high light outputting efficiency and front luminance is possible to be produced, when the diffusion sheet has a haze value of less than about 80%.

Further, in the case of this surface light emitter of Structure 2, when protrusions provided on a surface of the above-described light control sheet are formed in the form of a truncated cone contracted toward the above-described tip surfaces, an outputting efficiency of light emitted through this light control sheet is improved, and front luminance is further improved.

In the case of the surface light emitter of Structure 3 in the present invention, similarly to the surface light emitter of Structure 1, a large amount of light introduced into a light control sheet after passing through tip surfaces of protrusions of an attached light control sheet is totally reflected at the interface between the space portion and the protrusion, and light totally reflected is introduced into a light emission surface of the light control sheet to produce luminescence. As the result, a light outputting efficiency is improved, and front luminance is largely improved. In this case, since a specular image of a light control sheet, obtained via reflection on the mirror surface as a back surface of a surface light emitter after transmitting protrusions of the light control sheet, is observed, moire images are to be generated, but no moire fringe is visualized when a surface on the side of protrusions of the light control sheet and another surface on the opposite side are arranged to have a diffusion structure.

A situation where no moire fringe can be visualized with high light outputting efficiency and front luminance is possible to be produced, when the diffusion structure has a reflectance of less than 35%.

A situation where no moire fringe can be visualized with high front luminance can be accomplished, when the diffusion structure has a haze value of less than 70%.

A diffusion structure is provided on a parallel plate surface on which no protrusion is provided to measure a haze value of the diffusion structure provided on a light control sheet which is the value measured employing a haze meter (for example, HazeMeter NDH2000, manufactured by NIPPON DENSHOKU Industries Co., Ltd.).

Concerning a display device in conjunction with Structure 1 in the present invention, a display exhibiting high luminance can be produced, since high luminance light emitted from a light emission surface of the foregoing surface light emitter is introduced into the display element, when the display device is equipped with a display element and the above-described surface light emitter, and the surface light emitter is utilized as a backlight for the display element.

Next, the surface light emitters according to preferred embodiments in the present invention are specifically described referring to the attached drawings. In addition, the surface light emitter of the present invention is not limited to those shown in the following embodiments, but they may be allowed to be appropriately changed and implemented as long as the scope and intent of the present invention are not changed.

### Embodiment 1

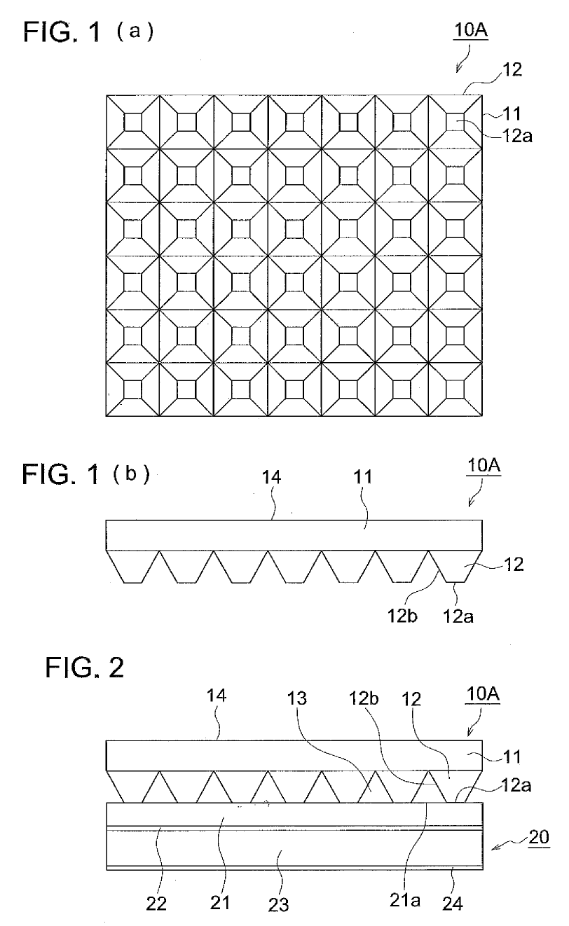

In Embodiment 1, as shown in FIG. 1(a) and FIG. 1(b), prism array sheet 10A, in which truncated square pyramid-shaped projections 12 whose tip sides are shrunk are successively formed on a surface of transparent substrate 11 in both the vertical and horizontal directions, is arranged to be used as a light control sheet. In addition, in the present specification, the shrunk tip sides of projections 12 mean that projections 12 are formed in such a way that they become gradually smaller toward the tip side from prism array sheet 10A, and as shown in FIG. 1(b) and the after-mentioned FIG. 2-9, the shape is like a boattail in the downward direction.

In the surface light emitter of Embodiment 1, as shown in FIG. 2, surface lightemitting device 20 composed of an organic EL device possessing organic EL layer 23 and facing electrode 24 provided on the surface of transparent substrate 21 having transparent electrode 22 thereon, and tip surfaces 12a of truncated square pyramid-shaped projections 12 in above-described prism array sheet 10A are arranged to be attached onto light emission surface 21a of transparent substrate 21 which emits light generated in surface light-emitting device 20. Herein, a specular surface having a reflectance of at least 80% is obtained since facing electrode 24 is made of metal such as aluminum or the like.

In such the way, when tip surfaces 12a of truncated square pyramid-shaped projections 12 in prism array sheet 10A are attached onto light emission surface 21a of surface light-emitting device 20, projections 12 of prism array sheet 10A become shrunk toward light emission surface 21a of surface light-emitting device 20, and space part 13 between projections 12 of prism array sheet 10A and light emission surface 21a of surface light-emitting device 20 gets filled with air having a lower refractive index than that of prism array sheet 10A.

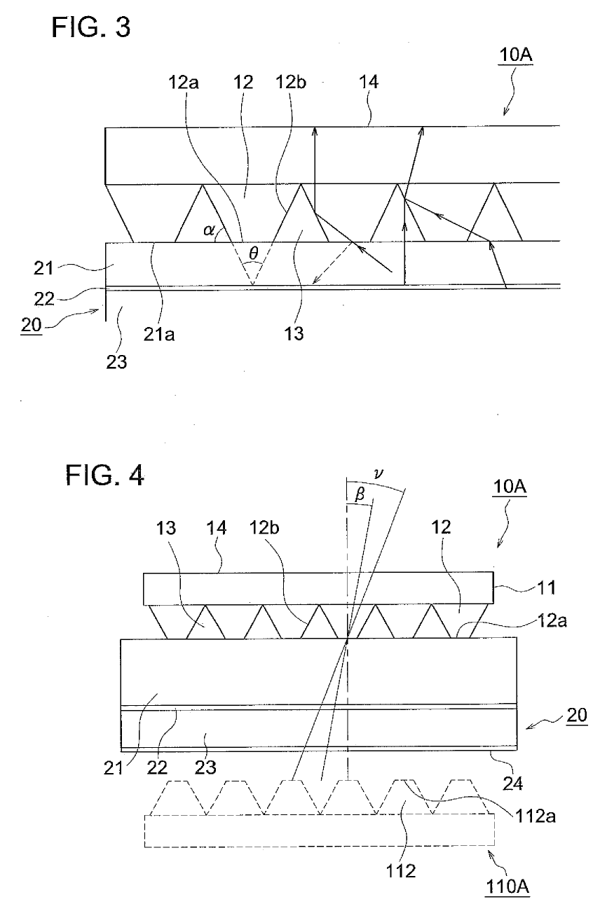

When tip surfaces 12a of truncated square pyramid-shaped projections 12 in prism array sheet 10A are attached onto light emission surface 21a of surface light-emitting device 20 in this manner to produce luminescence from surface light-emitting device 20, as shown in FIG. 3, light totally reflected on light emission surface 21a of surface light-emitting device 20, in cases where a light control sheet is not provided, is not totally reflected at the portion where tip surfaces 12a of projections 12 in prism array sheet 10A are attached, but is guided into the inside of prism array sheet 10A.

Further, light mostly guided into the inside of prism array sheet 10A in this manner is reflected at inclined surfaces 12b of projections 12 as the interface between space parts 13 and projections 12 shrunk toward light emission surface 21a in surface lightemitting device 20, and this reflected light is guided to light emission surface 14 in prism array sheet 10A to produce luminescence. In addition, as shown in FIG. 3, even though light is emitted from the portion of light emission surface 21a onto which tip surfaces 12a of projections 12 in prism array sheet 10A are not attached, light emitted vertically from light emission surface 21a has its direction of propagation modified slightly at inclined surfaces 12b of projections 12, but is to be emitted on the front side of prism array sheet 10A Light emitted at right angles to inclined surface 12b of projections 12 in prism array sheet 10A from light emission surface 21a is also guided into the inside of projections 12 from this inclined surfaces 12b, and reflected at inclined surface 12b on the opposite side of projections 12 to produce luminescence on the front side of prism array sheet 10A.

Herein, in order to suitably guide light totally reflected on light emission surface 21a of surface light-emitting device 20 into the inside of prism array sheet 10A from tip surfaces 12a of the above-described projections 12 when no light control sheet is provided as described above, it is preferable that the difference between a refractive index of prism array sheet 10A and a refractive index on light emission surface 21a in the above-described surface light-emitting device 20 is within 0.2.

In cases where truncated square pyramid-shaped projections 12 are provided in prism array sheet 10A as described above, when apex angle θ at the mutual intersection of inclined surfaces 12b of projection 12 becomes large and inclination angle α of inclined surfaces 12b of projections 12 with respect to light emission surface 21a in the above-described surface light-emitting device 20 becomes too small, this light does not impinge on inclined surfaces 12b of projections 12, is guided into light emission surface 14 of prism array sheet 10A, and is returned via total reflection generated on light emission surface 14 of prism array sheet 10A, even though light totally reflected on light emission surface 21a of surface light-emitting device 20 is guided into the inside of prism array sheet 10A in the case of no light control sheet being provided, whereby intensity of light emitted from light emission surface 14 of prism array sheet 10A is lowered.

On the other hand, when apex angle θ at the mutual intersection of inclined surfaces 12b of projection 12 becomes small and inclination angle α of inclined surfaces 12b of projections 12 with respect to light emission surface 21a in surface light-emitting device 20 becomes too large, light guided into the inside of prism array sheet 10A as described above is guided into space part 13 after passing through protrusions 12 with no reflection on inclined surface 12b of protrusions 12, and is further guided into the inside of prism array sheet 10A after passing through space part 13. And, this light is returned via total reflection generated on light emission surface 14 of prism array sheet 10A, whereby intensity of light emitted from light emission surface 14 of prism array sheet 10A is lowered.

Therefore, it is preferable that apex angle θ at the mutual intersection of inclined surfaces 12b of the above-described projections 12 satisfies the condition of (1/n−0.35)<sin θ<(1/n+0.3), where n is the refractive index of prism array sheet 10A with light having a wavelength of 550 nm, and it is more preferable that the apex angle θ at the mutual intersection of inclined surfaces 12b of the above-described projection 12 satisfies the condition of 1/n<sin θ<(1/n+0.25).

Further, when height h of projections 12, in general, is too low, though the possible range of height h of the above-described projections 12 changes depending on the above-described apex angle θ of projections 12 and pitch p of projections 12, this light does not impinge on inclined surfaces 12b of projections 12, is guided into light emission surface 14 of prism array sheet 10A, and is returned via total reflection generated on light emission surface 14 of prism array sheet 10A, even though light totally reflected on light emission surface 21a of surface light-emitting device 20 is guided into the inside of prism array sheet 10A in the case of no light control sheet being provided. On the other hand, when height h of projections 12 is too high, generated portions not utilized for reflection of light on inclined surfaces 12b of projections 12, and also when pitch p of projections 12 is the same pitch, the area of tip surfaces 12a of projections 12, which is attached onto light emission surface 21a of surface light-emitting device 20 becomes small, and hence the amount of light guided into the interior of this prism array sheet 10A becomes small, whereby an amount of light guided into the inside of prism array sheet 10A is reduced. Therefore, it is preferable that height h of projections 12 in relation to pitch p of protrusions 12 satisfies the condition of 0.28 p≦h≦1.1 p. In addition, when a transparent adhesive is employed as an adhering means, optical height h of the protrusions influencing an optical action can be lower than the height of the protrusions prior to adhering, since a part of the apex of protrusions 12 prior to adhering is embedded in an adhesive. Height h of protrusions 12 herein is designated as a height of the protrusion influencing an optical action after adhering.

In the surface light emitter described above, moire images are generated since a specular image of prism array sheet 10A is formed with facing electrode 24 having high reflectance, and superposition of the specular image with an image of the prism array image is observed. A mechanism thereof is described referring to FIG. 4.

Lighting is produced via light emission of surface light-emitting device 20 in prism array sheet 10A to form specular image 110A. In this case, portions of specular image 112a of light emission surfaces 12a of protrusions 12 of prism array sheet 10A become dark, and portions other than those become bright to observe the resulting specular image.

When observing specular image 112a through prism array sheet 10A, it is observed that light transmitted through light emission surfaces 12a of protrusions 12 produces bright images because of no bending of the light direction, and light transmitted through portions other than light emission surfaces 12a produces dark images because of bending of the light direction. Accordingly, an image obtained via superposition of prism array sheet 10A with specular image 110A is observed to be bright since bright portions of the specular image are observed to be bright in the direction of Angle ν from the normal direction with respect to the surface light emitter shown in FIG. 4, and an image obtained via superposition of prism array sheet 10A with specular image 110A is observed to be dark since dark portions of the specular image are observed through light emission surfaces 12a in the direction of Angle β from the normal direction

The direction relating to observation to be bright and the direction relating to observation to be dark are repeated depending on the observing direction, resulting in observation of moire fringes.

Generation principle of moire fringes produced by illuminating a prism sheet via luminescence of a surface light-emitting device itself has been described above, but moire fringes are similarly generated by illuminating a prism sheet from a lighting source present mainly on the side of an observer, which is different from a surface light emitter.

In order to reduce visibility of these moire fringes, since visibility of specular image 110A is reduced when making the area of light emission surfaces 12a protrusions 12 of prism array sheet 10A smaller, moire fringes can be arranged to be difficult to be observed. In this case, when prism array sheet 10A is exposed to parallel light, a ratio of an amount of light traveling in a straight line after entering prism array sheet 10A is reduced because of minimized area of light emission surfaces 12a, whereby a ratio of light bent by inclined surfaces 12b of projections 12 or the like becomes large. Since the ratio of light bent after entering parallel light can be measured as a haze value, visibility of observed moire fringes is reduced, provided that prism array sheet 10A has a larger haze value.

It has been found out in Embodiment 1 that moire fringes are observed by preparing a light control sheet in which an adhesion area ratio, that is, a ratio of area where light emission surfaces 12a of protrusions 12 of prism array sheet 10A are optically attached onto light emission surface 21a with respect to area of light emission surface 21a of a surface light-emitting device, is changed to measure a haze value thereof, so that contrast of observed moire fringes becomes sufficiently small in the case of a haze value of 85% or more, and the contrast of moiré fringes is reduced in such an extent that it is not visualized in the case of a haze value of 88% or more.

It has been also found out that the adhesion area ratio, together with the haze value is measured, so that contrast of moire fringes is reduced to a slight observation level when the adhesion area ratio is less than 20%, and moire fringes are hardly observed when the adhesion area ratio is less than 15%.

Herein, prism array sheet 10A is attached onto a transparent substrate made of the same material that of transparent substrate 21 in surface light-emitting device, and measured light enters from the transparent substrate side to measure a haze value employing a haze meter (HazeMeter NDH2000, manufactured by NIPPON DENSHOKU Industries Co., Ltd.).

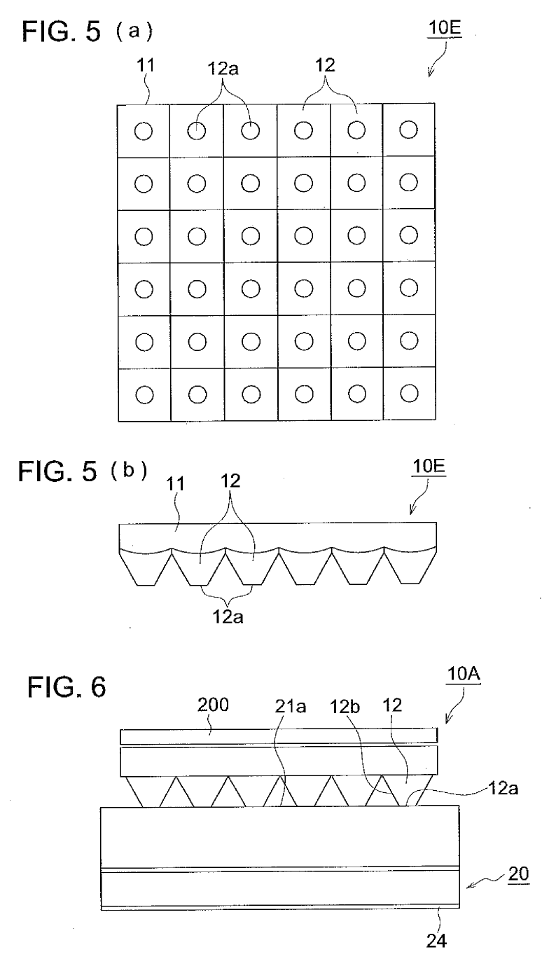

The truncated square pyramid shown in FIG. 1 is described as a shape of prism array sheet 10A for an example, but as shown in FIG. 5(a) and FIG. 5(b), prism array sheet 10E, in which those in the form of square obtained by cutting peripheral portions of truncated cone-shaped projections 12 whose tip sides are shrunk are successively formed on a surface of transparent substrate 11 in both the vertical and horizontal directions, may be used as a light control sheet.

Herein, when truncated cone-shaped projections 12 are arranged to be provided on prism array sheet 10E, front luminance of light emitted through this prism array sheet 10E is further to be improved. The detailed reason is unclear, but through considerable effort of the inventors, for example, since an apex angle formed by the ridge line in a cross section in the ridge line direction is smaller than an apex angle in a cross section in the line direction of truncated square pyramid-shaped protrusions 12 when protrusions 12 are truncated square pyramid-shaped as shown in FIG. 1, light emission which can not contribute sufficiently to improved front luminance is to be produced, but since an apex angle in a cross section in any direction remains constant in the case of truncated cone-shaped protrusions 12, in this case, the reason is presumably that light emission which can not contribute sufficiently to improved front luminance in the case of truncated square pyramid-shaped protrusions 12 is not produced.

Also in cases where protrusions 12 are truncated cone-shaped, the generation principle of moire fringes is possible to be considered to be the same case as that of truncated square pyramid which has already been described. In order to reduce visibility of moire fringes, it is effective to increase a haze value of prism array sheet 10E. The visibility of moire fringes is sufficiently reduced in the case of a haze value of at least 80%, and a haze value of at least 88% is further preferable.

A surface light emitter in Embodiment 1 described above, exhibits sufficiently reduced visibility of moire fringes together with high light outputting efficiently and front luminance.

In addition, cases where protrusions 12 of a prism array sheet are truncated square pyramid-shaped and truncated cone-shaped were described with a surface light emitter in Embodiment 1, but shapes exhibiting reduced visibility of moire fringes together with high light outputting efficiently and front luminance are not limited thereto. They may be also truncated triangular pyramid-shaped and truncated six-sided pyramid-shaped.

Further, an organic EL device is designed to be used as surface light-emitting device 20 in a surface light emitter of Embodiment 1, but surface light-emitting device 20 may be one which produces planar luminescence. Accordingly, an inorganic EL device and so forth are usable, but it is particularly effective to use an organic EL device which is still expected to further improve luminance.

### Embodiment 2

In Embodiment 2, truncated square pyramid-shaped projections 12 whose tip sides are shrunk is provided on a surface of transparent substrate 11 as a light control sheet, employing prism array sheet 10A shown in FIG. 1(a) and FIG. 1(b), similarly to the case of the above-described Embodiment 1.

Also in the case of a surface light emitter in Embodiment 1, similarly to the case of the above-described Embodiment 1, tip surface 12a of truncated square pyramid-shaped projections 12 in the above-described prism array sheet 10A was arranged to be attached onto light emission surface 21a of transparent substrate 21 to produce luminescence emitted from surface light-emitting device 20. As shown in FIG. 6, diffusion sheet 200 was also provided on the side of an observer.

In such the manner, also in a surface light emitter of Embodiment 2, similarly to the surface light emitter in Embodiment 1, light totally reflected on light emission surface 21a of surface light-emitting device 20 is guided into the inside of prism array sheet 10B with no total reflection at the portion attached onto tip surface 12a of projections 12 in prism array sheet 10A, and light mostly guided into the inside of prism array sheet 10A in this way is reflected on inclined surfaces 12b of projections 12 which become shrunk toward light emission surface 21a in surface light-emitting device 20. And this reflected light is to be guided into light emission surface 14 of prism array sheet 10B to produce luminescence.

Also in the case of a surface light emitter of Embodiment 2, visualized moire fringes are generated with a structure having surface light-emitting device 20 and prism array sheet 10A on account of the reason described in Embodiment 1, but it is possible to produce a situation where no moire fringes can be visualized by providing diffusion sheet 200 as shown in FIG. 6. Through studies on visibility of moire fringes employing diffusion sheets in various conditions, it was found out that no moire fringe was observed at all by arranging a diffusion sheet having a haze value of at least 30%. A sufficient effect tends to be produced even though a diffusion sheet further having a small haze value is employed, depending on extent of moire fringes generated in combination of surface light emitter 20 and prism array sheet 10A.

With respect to a purpose of reducing visibility of observed moire fringes, no problem is produced because of a high haze value, but there appears a problem such as a functioning trouble of prism array sheet 10A concerning improved light outputting efficiency, improved front luminance and so forth when the haze value is too high. After considerable effort during intensive studies, the inventors have found out that the light outputting efficiency and front luminance were sufficiently improved in combination of surface light-emitting device 20 and prism array sheet 10A when diffusion sheet 200 had a haze value of less than 80%. Further enhanced effect can also be obtained when the haze value was less than 65%.

Further, on account of the identical reason described in Embodiment 1, it is preferable that apex angle θ at the mutual intersection of inclined surfaces 12b of the above-described projections 12 in prism array sheet 10A satisfies the condition of (1/n−0.35)<sin θ<(1/n+0.3), where n is the refractive index of prism array sheet 10A with light having a wavelength of 550 nm, and it is more preferable that the apex angle θ at the mutual intersection of inclined surfaces 12b of the above-described projection 12 satisfies the condition of 1/n<sin θ<(1/n+0.25).

Further, on account of the identical reason described in Embodiment 1, it is preferable that height h of projections 12 in relation to pitch p of protrusions 12 in prism array sheet 10A satisfies the condition of 0.28 p≦h≦1.1 p. When satisfying such the condition, further enhanced light outputting efficiency and front luminance can be obtained.

An example of truncated square pyramid-shape shown in FIG. 1 was described as a shape of prism array sheet 10A, but prism array sheet 10E in which, those in the form of square obtained by cutting the peripheral part of truncated cone-shaped protrusions 12 whose tip sides are shrunk are successively formed on a surface of transparent substrate 11 in the vertical and horizontal directions, may also be utilized as a light control sheet as shown in FIG. 5(a) and FIG. 5(b).

Herein, when truncated cone-shaped protrusions 12 are arranged to be provided in prism array sheet 10E, front luminance of light emitted through prism array sheet 1E is further improved on account of the reason described in Embodiment 1.

### Embodiment 3

In Embodiment 3, similarly to the case of the above-described Embodiment 1, prism array sheet 10A shown in FIG. 1(a) and FIG. 1(b) is employed, and truncated square pyramid-shaped protrusions 12 whose tip sides are shrunk are provided on a surface of transparent substrate 11.

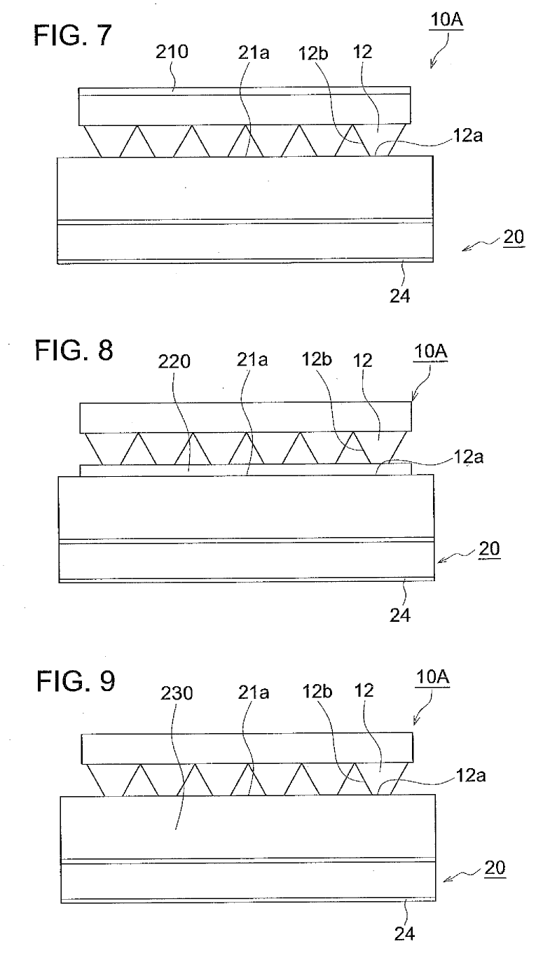

Also in the case of a surface light emitter in Embodiment 3, similarly to the above-described Embodiments 1 and 2, tip surfaces 12a of truncated square pyramid-shaped projections 12 in the above-described prism array sheet 10A is arranged to be attached onto light emission surface 21a of transparent substrate 21 to produce luminescence emitted from surface light-emitting device 20. As shown in FIG. 7, diffusion structure 210 was provided on the side of an observer.

In such the manner, also in a surface light emitter of Embodiment 3, similarly to the surface light emitter in Embodiments 1 and 2, light totally reflected on the light emission surface 21a of surface light-emitting device 20 is guided into the inside of prism array sheet 10B with no total reflection at the portion attached onto tip surface 12a of projections 12 in prism array sheet 10A, and light mostly guided into the inside of prism array sheet 10A in this way is reflected on inclined surfaces 12b of projections 12 which become shrunk toward light emission surface 21a in surface light-emitting device 20. And this reflected light is to be guided into light emission surface 14 of prism array sheet 10B to produce luminescence.

Visualized moire fringes are generated with a structure having surface light-emitting device 20 and prism array sheet 10A on account of the reason described in Embodiment 1, but it is possible to produce a situation where no moire fringes can be visualized by providing diffusion structure 210 as shown in FIG. 7. Through studies on visibility of moire fringes employing diffusion structures in various conditions, it was found out that no moire fringe was observed at all by arranging a diffusion sheet having a haze value of at least 30%. A sufficient effect tends to be produced even though diffusion structure 210 further having a small haze value is employed, depending on extent of moire fringes generated in combination of surface light emitter 20 and prism array sheet 10A. Herein, usable diffusion structure means beads diffusion, diffusion by surface roughness or the like.

Herein, there appears a problem such as a functioning trouble with respect to improved light outputting efficiency, improved front luminance and so forth when a haze value of the diffusion structure is too high. After considerable effort during intensive studies, the inventors have found out that the light outputting efficiency and front luminance of the surface light emitter were sufficiently improved when diffusion structure 210 had a haze value of less than 70%. Further enhanced effect can also be obtained when the haze value was less than 65%. It was also found out that sufficient light outputting efficiency was possible to be obtained even though diffusion structure 210 having a reflectance of at least 30% was employed. Herein, the haze value and reflectance were measured with a haze meter and so forth, after forming the diffusion structure on a sheet made of the same material, which has no prism line.

Further, on account of the identical reason described in Embodiment 1, it is preferable that apex angle θ at the mutual intersection of inclined surfaces 12b of the above-described projections 12 in prism array sheet 10A satisfies the condition of (1/n−0.35)<sin θ<(1/n+0.3), where n is the refractive index of prism array sheet 10A with light having a wavelength of 550 nm, and it is more preferable that the apex angle θ at the mutual intersection of inclined surfaces 12b of the above-described projection 12 satisfies the condition of 1/n<sin θ<(1/n+0.25).

Further, on account of the identical reason described in Embodiment 1, it is preferable that height h of projections 12 in relation to pitch p of protrusions 12 in prism array sheet 10A satisfies the condition of 0.28 p≦h≦1.1 p. When satisfying such the condition, further enhanced light outputting efficiency and front luminance can be obtained.

An example of truncated square pyramid-shape shown in FIG. 1 was described as a shape of prism array sheet 10A, but prism array sheet 10E in which, those in the form of square obtained by cutting the peripheral part of truncated cone-shaped protrusions 12 whose tip sides are shrunk are successively formed on a surface of transparent substrate 11 in the vertical and horizontal directions, may also be utilized as a light control sheet as shown in FIG. 5(a) and FIG. 5(b).

Herein, when truncated cone-shaped protrusions 12 are arranged to be provided in prism array sheet 10E, front luminance of light emitted through prism array sheet 10E is further improved on account of the reason described in Embodiment 1.

Further, an effect of accomplishing a thin type together with a simple structure rather than a structure in which a diffusion sheet is separately provided can be obtained by producing a surface of a light control sheet so as to give a diffusion structure on the surface.

### Embodiment 4

In Embodiment 4, as shown in FIG. 8, tip surfaces 12a of truncated square pyramid-shaped projections 12 in prism array sheet 10A were attached through adhesive diffusion layer 220 to light emission surface 21a of transparent substrate 21 which emits light generated in surface light emitting device 20.

As described in Embodiment 1, since an amount of light passing through with no curving on tip surfaces 12a of protrusions 12 is desired to be large in order to improve visibility of moire fringes, an adhesive layer obtained after attaching tip surfaces 12a onto light emission surface 21a of transparent substrate 21 is arranged to be set to adhesive diffusion layer 220 exhibiting diffuseness to produce an effect of largely reducing visibility of moire fringes.

Further, produced is no effect at all with respect to the direction in which light is output from wall surfaces 12b of protrusions 12, and light curved in the front direction, light outputting efficiency and front luminance can be improved.

### Embodiment 5

In Embodiment 5, as shown in FIG. 9, a transparent substrate to produce luminescence emitted in surface light-emitting device 20 was arranged to be set to diffusion substrate 230 having a diffusion structure, and tip surfaces 12a of truncated square pyramid-shaped projections 12 in prism array sheet 10A were attached onto the light emission surface 21a.

As described in Embodiment 1, since visibility of a specular image of prism array sheet 10A is high in order to improve visibility of moire fringes, a transparent substrate to form light-emitting device 20 is to possess diffuseness to produce diffusion substrate 230, whereby an effect of largely reducing visibility of moire fringes can be produced.

Further, produced is no effect at all with respect to the direction in which light is output from wall surfaces 12b of protrusions 12, and light curved in the front direction, light outputting efficiency and front luminance can be improved.

The surface light emitter of the present invention is usable as a backlight for various display devices such as an organic EL display, an inorganic EL display and a PDP (plasma display). Further, the surface light emitter of the present invention is preferably utilized as a backlight for a reflection type, a transmission type or a semi-transmission type LCD, and as backlights for various driving system LCDs such as a TN type LCD, an STN type LCD, an OCB type LCD, an HAN type LCD, a VA type LCD (PVA type LCD or MVA type LCD) and an IPS type LCD.

### EXAMPLES

Next, surface light emitters of the embodiment in the present invention is compared with those in the Comparative example, and it is to be described that in the case of the surface light emitters of the embodiment in the present invention, front luminance and an outputting efficiency of light emitted from the surface light emitter are largely improved, and excellent light emitters in which no moire fringes are observed.

### Comparative Example 1

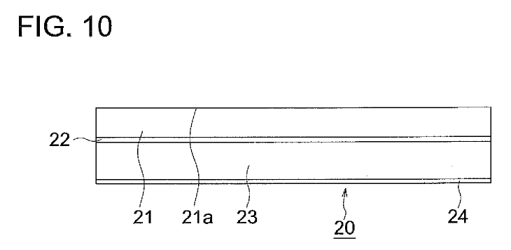

In Comparative example 1, as is shown in FIG. 10, surface light-emitting device 20 was used as it is as the surface light emitter.

Surface light-emitting device 20 composed of an organic EL device possessing organic EL layer 23 and facing electrode 24 provided on the surface of transparent substrate 21 fitted with a transparent electrode was prepared to be used as this surface light-emitting device 20.

Herein, in this surface light-emitting device 20, an alkali-free glass having a size of 40 mm×52 mm with a thickness of 0.7 mm was used as the above-described transparent substrate 21, and a 150 nm thick ITO film was formed on a surface of this transparent substrate 21 as transparent electrode 22, patterning in the form of an electrode shape was conducted via photolithography to prepare a size of 35×46 mm. In addition, resistance of this transparent electrode 22 was measured employing Lorester manufactured by Mitsubishi Chemical Corp. and then, 20Ω/□ was obtained.

A triazole derivative was used as a hole transport material, and a hole transport layer having a thickness of 100 nm was formed on this transparent electrode 22 via vacuum deposition. Next, a luminescent material made of tris (8-quinolinolat) was evaporated on this hole transport layer via vacuum evaporation to form an emission layer having a thickness 100 nm. Then, a triazine derivative was evaporated on this emission layer via vacuum evaporation to form a hole blocking layer having a thickness 100 nm. Further, a nitro-substituted fluorene derivative was evaporated on this hole blocking layer via vacuum evaporation to form an electron transport layer having a thickness of 100 nm. Next, facing electrode 24 made of aluminum and having a thickness of 100 nm was formed on this electron transport layer via sputtering. In addition, transparent substrate 21 on the side of light emission surface 21a of this surface light-emitting device 20 had a refractive index of 1.517 with respect to light having a wavelength of 550 nm.

### Comparative Example 2

In Comparative example 2, similarly to the surface light emitter of the foregoing embodiment 1, prism array sheet 10A, in which truncated square pyramid-shaped projections 12 were successively formed on a surface of transparent substrate 11 as a light control sheet, was employed, and as shown in FIG. 2, triangular pillar-shaped projections 12 in this prism array sheet 10A was placed facing light emission surface 21a of surface light-emitting device 20 in the above-described Comparative example 1 to attach this prism array sheet 10A onto light emission surface 21a of surface light-emitting device 20. An adhesive was employed as an adhering method. The thickness of the adhesive was 10 μm. Height of the protrusion before adhering was compared with height h of the protrusion after adhering, it was understood that 5 μm of the tip portion in length of the protrusion was buried. In addition, this prism array sheet 10A has a refractive index of 1.495 with respect to light having a wavelength of 550 nm, apex angle θ of the above-described triangular pillar-shaped projections 12 shown in FIG. 5 was 50°, height of truncated square pyramid-shaped projections 12 was 20.4 μm, and this protrusions 12 had a pitch of 35 μm. Height of the protrusions after adhering was 15.4 μm.

### Comparative Examples 3-4

The experiment with Comparative examples 3-4 were conducted similarly to that of Comparative example 2, except that height of protrusions 12 of the prism array sheet was replaced by each of 16.9 μm and 9.9 μm. The height of the protrusions after adhering was each of 11.9 μm and 4.9 μm.

### Comparative Example 5

In Comparative example 5, protrusions 12 of the prism array sheet were truncated cone-shaped, apex angle θ of protrusions 12 was 42°, protrusions 12 had a height of 20.4 μm, protrusions 12 had a pitch of 35 μm. The height of the protrusions after adhering was 15.4 μm.

### Example 1

In Example 1, as shown in Embodiment 1, prism array sheet 10A, in which truncated square pyramid-shaped projections 12 whose tip sides are shrunk are successively formed on a surface of transparent substrate 11 in both the vertical and horizontal directions, is used as a light control sheet, and tip surfaces 12a of truncated square pyramid-shaped projections 12 in this prism array sheet 10A are arranged to be attached onto light emission surface 21a of surface light-emitting device 20. In addition, this prism array sheet 10A had a refractive index of 1.495 with respect to light having a wavelength of 550 nm, truncated square pyramid-shaped projections 12 had a apex angle θ of 50° and a height of 30.9 μm, and projections 12 had a pitch of 35 μm. The height of the protrusions after adhering was 25.9 μm.

### Examples 2-3

In Examples 2-3, protrusions 12 of the prism array sheet were truncated cone-shaped, protrusions 12 had a height of each of 28.1 μm and 24.6 μm, and protrusions 12 had a pitch of 35 μm. The height of the protrusions after adhering was each of 23.1 μm and 19.6 μm.

A surface light-emitting device fitted with a surface light emitter of each of the above-described Comparative examples 1-5 and Examples 1-3 was operated to emit light to measure front luminance and light outputting efficiency of each surface light emitter, when each of the front luminance and the light outputting efficiency in the above-described Comparative example 1 was set to 1. Luminance in the direction at a predetermined angle to the normal line in a plane possessing the normal line was measured while changing the angle employing an angle-luminance measuring device, when the normal line of a surface light emitter was set to 0°, and the value as a light outputting efficiency obtained by integrating the luminance at each angle was compared with the value of Comparative example 1.

Further, the surface lightemitting device was operated to emit light, and the prism array sheet was observed with a microscope to measure the adhesion area ratio.

Further, the surface light emitter was visually observed to confirm visibility of moire fringes.

Results of front luminance, light outputting efficiency and moire fringes of Comparative examples 1-5 and Examples 1-3 are shown in Table 1.

TABLE 1

| | | | | | | | | Haze value | |
|---|---|---|---|---|---|---|---|---|---|
| | | | Apex | | Adhesion | | Light | of light | |
| | Shape of light | Pitch | angle | Height | area | Front | outputting | control | Moire |
| | control sheet | (μm) | (°) | (μm) | ratio | luminance | efficiency | sheet (%) | fringes |
| Comparative | No light control | — | — | — | — | 1.00 | 1.00 | — | — |
| example 1 | sheet provided | | | | | | | | |
| Comparative | Truncated square | 35 | 50 | 15.4 | 35% | 1.70 | 1.50 | 80 | Observed |
| example 2 | pyramid | | | | | | | | |
| Comparative | Truncated square | 35 | 50 | 11.9 | 47% | 1.63 | 1.55 | 70 | Observed |
| example 3 | pyramid | | | | | | | | |
| Comparative | Truncated square | 35 | 50 | 4.9 | 76% | 1.48 | 1.50 | 45 | Observed |
| example 4 | pyramid | | | | | | | | |
| Comparative | Truncated cone | 35 | 42 | 15.4 | 34% | 1.83 | 1.55 | 83 | Observed |
| example 5 | | | | | | | | | |
| Example 1 | Truncated square | 35 | 50 | 25.9 | 10% | 1.93 | 1.55 | 89 | Hardly |
| | pyramid | | | | | | | | observed |
| Example 2 | Truncated cone | 35 | 50 | 23.1 | 12% | 2.30 | 1.45 | 88 | Hardly |
| | | | | | | | | | observed |
| Example 3 | Truncated cone | 35 | 50 | 19.6 | 18% | 2.56 | 1.55 | 87 | Slightly |
| | | | | | | | | | observed |

From this result, moire fringes were observed in Comparative examples 2-5, but in the case of Examples 1-3, moire fringes were slightly observed or hardly observed. Prism array sheets of Comparative examples 2-5 had a haze value of less than 85%, but prism array sheets of Examples 1-3 had a haze value of 85% or more.

Further, adhesion area ratios of Comparative examples 2-5 are 30% or more as high values, but adhesion area ratios of Examples 1-3 are less than 20% as low values.

### Comparative Examples 6-7

In Comparative examples 6-7, similarly to the case of the above-described Embodiment 2, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 6, diffusion sheet 200 was provided on the observer side from prism array sheet 10A.

A prism array sheet described in Comparative example 2 was used as this prism array sheet 10A. As diffusion sheet 200, diffusion plate D114 produced by TSUJIDEN Co., Ltd. was used in Comparative example 6, and diffusion plate D123 produced by TSUJIDEN Co., Ltd. was used in Comparative example 7.

### Examples 5-8

In Examples 5-8, similarly to the case of the above-described Embodiment 2, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 6, diffusion sheet 200 was provided on the observer side from prism array sheet 10A.

A prism array sheet described in Comparative example 2 was used as this prism array sheet 10A. As diffusion sheet 200, diffusion plate D120 produced by TSUJIDEN Co., Ltd. was used in Example 5, diffusion plate D129 produced by TSUJIDEN Co., Ltd. was used in Example 6, diffusion plate D132 produced by TSUJIDEN Co., Ltd. was used in Example 7, and diffusion plate D134 produced by TSUJIDEN Co., Ltd. was used in Example 8.

### Comparative Examples 8-9

In Comparative examples 8-9, similarly to the case of the above-described Embodiment 2, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 6, diffusion sheet 200 was provided on the observer side from prism array sheet 10A.

A prism array sheet described in Comparative example 5 was used as this prism array sheet 10A. As diffusion sheet 200, diffusion plate D114 produced by TSUJIDEN Co., Ltd. was used in Comparative example 8, and diffusion plate D123 produced by TSUJIDEN Co., Ltd. was used in Comparative example 9.

### Examples 9-12

In Examples 9-12, similarly to the case of the above-described Embodiment 2, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 6, diffusion sheet 200 was provided on the observer side from prism array sheet 10A.

A prism array sheet described in Comparative example 5 was used as this prism array sheet 10A. As diffusion sheet 200, diffusion plate D120 produced by TSUJIDEN Co., Ltd. was used in Example 9, diffusion plate D129 produced by TSUJIDEN Co., Ltd. was used in Example 10, diffusion plate D132 produced by TSUJIDEN Co., Ltd. was used in Example 11, and diffusion plate D134 produced by TSUJIDEN Co., Ltd. was used in Example 12.

### Comparative Examples 10-11

In Comparative examples 10-11, similarly to the case of the above-described Embodiment 2, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 6, diffusion sheet 200 was provided on the observer side from prism array sheet 10A.

A prism array sheet described in Comparative example 3 was used as this prism array sheet 10A. As diffusion sheet 200, diffusion plate D114 produced by TSUJIDEN Co., Ltd. was used in Comparative example 10, and diffusion plate D123 produced by TSUJIDEN Co., Ltd. was used in Comparative example 11.

### Examples 13-16

In Examples 13-16, similarly to the case of the above-described Embodiment 2, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 6, diffusion sheet 200 was provided on the observer side from prism array sheet 10A.

A prism array sheet described in Comparative example 3 was used as this prism array sheet 10A. As diffusion sheet 200, diffusion plate D120 produced by TSUJIDEN Co., Ltd. was used in Example 13, diffusion plate D129 produced by TSUJIDEN Co., Ltd. was used in Example 14, diffusion plate D132 produced by TSUJIDEN Co., Ltd. was used in Example 15, and diffusion plate D134 produced by TSUJIDEN Co., Ltd. was used in Example 16.

Measured results of front luminance, light outputting efficiency and moire fringes of Comparative examples 6-11 and Examples 5-16 are shown in Table 2.

TABLE 2

| | Shape | Product No. of | Haze value | | | | |
|---|---|---|---|---|---|---|---|
| | of | diffusion plate | of light | Trans- | | Light | |
| | prism | produced by | control | mittance | Front | outputting | |
| | sheet | TSUJIDEN Co., Ltd. | sheet (%) | (%) | luminance | efficiency | Moire fringes |
| Comp. 6 | *1 | D114 | 81.4 | 61.5 | 1.72 | 1.35 | Not observed at all |
| Comp. 7 | *1 | D123 | 82.4 | 55 | 1.63 | 1.33 | Not observed at all |
| Example 5 | *1 | D120 | 76 | 82.5 | 1.74 | 1.48 | Not observed at all |
| Example 6 | *1 | D129 | 65 | 87 | 1.70 | 1.52 | Not observed at all |
| Example 7 | *1 | D132 | 50 | 88 | 1.71 | 1.50 | Not observed at all |
| Example 8 | *1 | D134 | 30 | 89 | 1.69 | 1.53 | Not observed at all |
| Comp. 8 | *2 | D114 | 81.4 | 61.5 | 1.80 | 1.35 | Not observed at all |
| Comp. 9 | *2 | D123 | 82.4 | 55 | 1.49 | 1.30 | Not observed at all |
| Example 9 | *2 | D120 | 76 | 82.5 | 1.89 | 1.45 | Not observed at all |
| Example 10 | *2 | D129 | 65 | 87 | 1.86 | 1.52 | Not observed at all |
| Example 11 | *2 | D132 | 50 | 88 | 1.82 | 1.52 | Not observed at all |
| Example 12 | *2 | D134 | 30 | 89 | 1.80 | 1.53 | Not observed at all |
| Comp. 10 | *3 | D114 | 81.4 | 61.5 | 1.94 | 1.30 | Not observed at all |
| Comp. 11 | *3 | D123 | 82.4 | 55 | 1.82 | 1.35 | Not observed at all |
| Example 13 | *3 | D120 | 76 | 82.5 | 2.22 | 1.45 | Not observed at all |
| Example 14 | *3 | D129 | 65 | 87 | 2.35 | 1.42 | Not observed at all |
| Example 15 | *3 | D132 | 50 | 88 | 2.53 | 1.52 | Not observed at all |
| Example 16 | *3 | D134 | 30 | 89 | 2.54 | 1.53 | Not observed at all |

*1: Truncated square pyramid of Comparative example 2,
Comp.: Comparative example
*2: Truncated cone of Comparative example 5,
*3: Truncated cone of Example 3

From this result, no moire fringe was observed at all in Comparative examples 6-11 and Examples 5-16. Comparative examples 6-11 employing a diffusion plate having a haze value of at least 80% had a haze value of less than 85% had an insufficient light outputting efficiency of less than 1.4, but Examples 5-16 employing a diffusion plate having a haze value of less than 80% exhibited high performance such as a light outputting efficiency of 1.4 or more, together with a front luminance of 1.6 or more.

### Comparative Example 12

In Comparative example 12, similarly to the case of the above-described Embodiment 3, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 7, diffusion structure 210 was provided on the observer side from prism array sheet 10A.

A prism array sheet described in Comparative example 2 was used as this prism array sheet 10A. As diffusion structure 210, a beads distribution type distribution structure was used in Comparative example 12, and its reflectance was 40%. Herein, a diffusion sheet composed of transparent substrate 11 possessing no prism array and diffusion structure 210 was prepared, and exposed to light from the side of no diffusion structure for measurements

### Examples 17-21

In Examples 17-21, similarly to the case of the above-described Comparative example 12, prism array sheet 10A shown in FIG. 1(a) and FIG. 1(b) is used as a light control sheet, and truncated square pyramid-shaped projections 12 whose tip sides are shrunk are formed on a surface of transparent substrate 11. Tip surfaces 12a of truncated square pyramid-shaped projections 12 in the above-described prism array sheet 10A were arranged to be attached onto light emission surface 21a of transparent substrate 21 to produce luminescence emitted in surface light-emitting device 20. Together with this, as shown in FIG. 7, diffusion sheet 210 was provided on the observer side from prism array sheet 10A.

A prism array sheet described in Comparative example 2 was used as this prism array sheet 10A. The beads diffusion type was used as a diffusion structure. The reflectance of the diffusion structure in Examples 17-21 is shown in Table 3.

Measured results of front luminance, light outputting efficiency and moire fringes of Comparative example 7 and Examples 17-21 are shown in Table 3.

From this result, no moire fringe was observed at all in Comparative example 7 and Examples 17-21. It was understood that insufficient performance of a light outputting efficiency of less than 1.5 and a front luminance of less than 1.7 was obtained in Comparative example 12. In the case of Examples 17-21, high performance exhibiting a light outputting efficiency of not less than 1.5 and a front luminance of not less than 1.7 was able to be obtained.

### Comparative Example 13

A surface light emitter in the same structure as that in Comparative example 12 was employed, except that a prism array sheet with truncated cone-shaped protrusions was used as a light control sheet in Comparative example 13. A prism array sheet in the same shape as that in Example 3 was used as a prism array sheet. A beads diffusion type diffusion plate was used in Comparative example 13 as diffusion structure 210, which had a haze value of 82.4%, and a reflectance of 40.0%.

### Examples 22-26

The same surface light emitter as that in the above-described Comparative example 13 was used in Examples 22-26. The reflectance of the diffusion structure in Examples 22-26 is shown in Table 3.

As to the surface light emitters in Comparative example 13 and Examples 22-26, the surface light emitters are operated to produce luminescence to measure front luminance, light outputting efficiency and moire fringes, and measured results are shown in Table 3.

TABLE 3

| | | Reflec- | Front | Light | |
|---|---|---|---|---|---|
| | Prism | tance | lumi- | outputting | Moire |
| | sheet shape | (%) | nance | efficiency | fringes |
| Comp. 12 | truncated | 40 | 1.52 | 1.47 | Not |
| | square pyramid | | | | observed |
| | of Comp. 2 | | | | at all |
| Ex. 17 | truncated | 33.5 | 1.68 | 1.53 | Not |
| | square pyramid | | | | observed |
| | of Comp. 2 | | | | at all |
| Ex. 18 | truncated | 12.5 | 1.68 | 1.53 | Not |
| | square pyramid | | | | observed |
| | of. Comp. 2 | | | | at all |
| Ex. 19 | truncated | 8 | 1.64 | 1.54 | Not |
| | square pyramid | | | | observed |
| | of Comp. 2 | | | | at all |
| Ex. 20 | truncated | 7 | 1.68 | 1.58 | Not |
| | square pyramid | | | | observed |
| | of Comp. 2 | | | | at all |
| Ex. 21 | truncated | 6 | 1.70 | 1.53 | Not |
| | square pyramid | | | | observed |
| | of Comp. 2 | | | | at all |
| Comp. 13 | truncated cone | 40 | 1.55 | 1.48 | Not |
| | of Ex. 3 | | | | observed |
| | | | | | at all |
| Ex. 22 | truncated cone | 33.5 | 1.88 | 1.50 | Not |
| | of Ex. 3 | | | | observed |
| | | | | | at all |
| Ex. 23 | truncated cone | 12.5 | 2.10 | 1.51 | Not |
| | of Ex. 3 | | | | observed |
| | | | | | at all |
| Ex. 24 | truncated cone | 8 | 2.43 | 1.54 | Not |
| | of Ex. 3 | | | | observed |
| | | | | | at all |
| Ex. 25 | truncated cone | 7 | 2.54 | 1.55 | Not |
| | of Ex. 3 | | | | observed |
| | | | | | at all |
| Ex. 26 | truncated cone | 6 | 2.55 | 1.53 | Not |
| | of Ex. 3 | | | | observed |
| | | | | | at all |

Comp.: Comparative example
Ex.: Example

From this result, no moire fringe was observed at all in Comparative example 13 and Examples 22-26.

It was also understood that insufficient performance of a front luminance of less than 1.6 was obtained in Comparative example 13. In the case of Examples 22-26, high performance exhibiting a front luminance of not less than 1.6 was able to be obtained.

Next, it was understood that a liquid crystal display device exhibiting excellent luminance was able to be obtained by utilizing surface light emitters of Examples 1-26 in the present invention in place of a backlight installed in advance for 15 inch size display VL-150SD manufactured by Fujitsu Ltd.

1. A surface light emitter comprising a light control sheet and a surface light-emitting device,
wherein the light control sheet comprises protrusions provided on a surface of the light control sheet, and tip portions of the protrusions are attached to a light emission surface of the surface light-emitting device through an adhesion layer, and
wherein the light control sheet has a haze value of at least 85%.

2. A surface light emitter comprising a diffusion sheet, a light control sheet and a surface light-emitting device,
wherein the light control sheet comprises protrusions provided on a surface of the light control sheet; tip portions of the protrusions are attached to a light emission surface of the surface light-emitting device through an adhesion layer; and the diffusion sheet is provided on an opposite side surface of the light control sheet with respect to a surface of the light control sheet brought into contact with the surface light-emitting device, and
wherein the light control sheet has a haze value of less than 80%.

3. A surface light emitter comprising a light control sheet and a surface light-emitting device,
wherein the light control sheet comprises protrusions provided on a surface of the light control sheet and a diffusion structure provided on another surface of the light control sheet, and tip portions of the protrusions are attached to a light emission surface of the surface light-emitting device through an adhesion layer, and
wherein the diffusion structure has a reflectance of less than 35%.

4. A surface light emitter comprising a light control sheet and a surface light-emitting device,
wherein the light control sheet comprises protrusions provided on a surface of the light control sheet, and tip portions of the protrusions are attached to a light emission surface of the surface light-emitting device through an adhesion layer, and
wherein the adhesion layer has a diffusion structure.

5. A surface light emitter comprising a light control sheet and a surface light-emitting device,
wherein the light control sheet comprises protrusions provided on a surface of the light control sheet, and tip portions of the protrusions are attached to a light emission surface of the surface light-emitting device through an adhesion layer, and
wherein the surface light-emitting device comprises a surface of a transparent substrate having a diffusion structure as a light emission surface.

6. The surface light emitter of, claim 1 wherein the protrusions are truncated cone-shaped.

7. A display device comprising the surface light emitter of claim 1 as a backlight.

8. The surface light emitter of claim 2,
wherein the protrusions are truncated cone-shaped.

9. The surface light emitter of claim 3,
wherein the protrusions are truncated cone-shaped.

10. The surface light emitter of claim 4,
wherein the protrusions are truncated cone-shaped.

11. The surface light emitter of claim 5,
wherein the protrusions are truncated cone-shaped.

12. A display device comprising the surface light emitter of claim 2 as a backlight.

13. A display device comprising the surface light emitter of claim 3 as a backlight.

14. A display device comprising the surface light emitter of claim 4 as a backlight.

15. A display device comprising the surface light emitter of claim 5 as a backlight.

16. A display device comprising the surface light emitter of claim 6 as a backlight.
